(19) United States
(12) Patent Application Publication
(10) Pub. No.: US 2002/0164876 A1
(43) Pub. Date: Nov. 7, 2002

(54) Method for finishing polysilicon or amorphous substrate structures

(76) Inventors: Hans S. Walitzki, Portland, OR (US); Howard W. Hogle, Portland, OR (US); Wing S. Luk, Portland, OR (US); Claudian R. Nicolesco, Portland, OR (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 10/054,697

(22) Filed: Jan. 18, 2002

Related U.S. Application Data
(63) Continuation-in-part of application No. 09/843,028, filed on Apr. 25, 2001, now abandoned.
(63) Continuation-in-part of application No. 09/843,241, filed on Apr. 25, 2001, now abandoned.
(63) Continuation-in-part of application No. 09/843,240, filed on Apr. 25, 2001.
(60) Provisional application No. 60/199,466, filed on Apr. 25, 2000.
(60) Provisional application No. 60/199,613, filed on Apr. 25, 2000.
(60) Provisional application No. 60/199,611, filed on Apr. 25, 2000.
(60) Provisional application No. 60/199,612, filed on Apr. 25, 2000.
(60) Provisional application No. 60/199,660, filed on Apr. 25, 2000.

(51) Int. Cl. H01L 21/302; H01L 21/461

(52) U.S. Cl. 438/692; 438/693

(57) ABSTRACT

According to the invention, a method for preparing multicrystalline substrates as “handle wafers” for subsequent bonding to “device layer” quality materials is disclosed. In one step, starting with a suitable substrate such as multicrystalline silicon, the substrate surface is prepared for layer transfers by using a novel CMP method in which, after a suitable period of polishing at elevated pH, a surfactant and rinse material is gradually introduced into the slurry to lower pH and remove wear materials from the slurry. In another step, a filler layer of polycrystalline silicon is transferred to the face of the polished substrate to a predetermined thickness, thus filling in surface defects remaining after the initial CMP step, and a subsequent CMP polishing step is performed. By these steps, multicrystalline substrates can be prepared with surface roughness of twenty Angstroms or less, which is suitable for defect-free bonding to device-layer materials in this embodiment.

This application claims the benefit of and is a continuation in part of U.S. application Ser. No. 09/843,028 filed on Apr. 25, 2001, U.S. application Ser. No. 09/843,241 filed on Apr. 25, 2001, and U.S. application Ser. No. 09/843,240 filed Apr. 25, 2001, each of which is incorporated herein by reference. Further, U.S. application Ser. No. 09/843,028 is a non-provisional of U.S. Provisional Application Ser. Nos. 60/199,466, 60/199,613 and 60,199,611, all filed Apr. 25, 2000 and all claimed benefit to for this application. Further still, U.S. application Ser. No. 09/843,241 is a non-provisional of U.S. Provisional Patent Ser. No. 60/199,612 filed on Apr, 25, 2000, which this application also claims benefit to. Further yet, U.S. application Ser. No. 09/843,240 is a non-provisional of U.S. Provisional Patent Ser. No. 60/199,660 filed on Apr. 25, 2000, which this application also claims benefit to.

### BACKGROUND OF THE INVENTION

The present invention relates to silicon wafer structures and, more specifically, to the manufacture of substrate structures for wafer-to-wafer bonding applications.

Since semiconductor device functions are normally only performed in a very shallow region on the front surface of silicon wafers, the bulk of the silicon wafer serves only as a mechanical carrier. Yet, for more demanding semiconductor applications including, but not limited to, the manufacture of microelectronic mechanical structures (MEMS), micro-opto-electronic mechanical structures (MOEMS), and complex integrated circuits such as microprocessors (many of which are built using silicon-on-insulator (SOI) technology well-known in the art), expensive substrates such as monocrystalline silicon are required in order to ensure that the total thickness variation (TTV) of the wafer is within a range of less than 0.5 nm. This narrow range is typically required in order to ensure defect-free bonding of transferred layers to the substrate, as when an insulating oxide layer is transferred in silicon-on-insulator applications.

Multicrystalline silicon, formed from the controlled solidification of molten silicon, is well-established within the solar cell field as an inexpensive source of silicon wafers. However, because polishing of silicon wafers is usually performed using a Chemical-Mechanical Planarization (CMP) process, this material has heretofore not been suitable for SOI and other demanding semiconductor applications because CMP applied to multicrystalline silicon produces surface variations on the order of 5 nm, an order of magnitude greater than the tolerances required. CMP is normally conducted using alkali slurry (typically pH is maintained between 10.5-11.0) of silica (SiO₂) particles. The pH limitation is required because this causes the chemical activity of silica acting on the wafer surface to dominate the polishing process, which is necessary to achieve economically satisfactory reaction rates. However, this chemical removal of surface material occurs at different rates for each of the grains within the multicrystalline silicon, and in particular it acts most rapidly at grain boundaries. This effect causes the formation of surface defects which persist in the range of 5 nm typical defect depth regardless of the amount of time used in the CMP process. The present invention provides a method for overcoming these issues and using less-expensive substrate materials such as multicrystalline silicon for the production of silicon wafer substrates with TTV of less than 0.5 nm, which are suitable for use in SOI, MEMS, MOEMS and other applications which require TTV tolerances in this range.

### BRIEF DESCRIPTION OF THE DRAWINGS

The present invention is described in conjunction with the appended figures:

FIG. 1 is a cross-sectional view of a prior art depiction of the chemical-mechanical-planarization (CMP) process used in the art, before the starting of polishing;

FIG. 2 is a cross-sectional view of a prior art depiction that shows the same CMP process used in the art of FIG. 1, after polishing has started;

FIG. 3 is a cross-sectional view of a prior art depiction that shows the results of the same prior art CMP process of FIG. 2;

FIG. 4 is a cross-sectional view of depiction an embodiment of the results of the CMP process applied according to the present invention;

FIG. 5 is a cross-sectional view that shows an embodiment of a multicrystalline silicon substrate after application of a filler layer;

FIG. 6 is a cross-sectional view that shows an embodiment of the same substrate with filler layer of FIG. 5, after polishing;

FIG. 7 is a cross-sectional view that shows an embodiment of the final result of the application of the invention in a silicon-on-insulator application; and

FIG. 8 is a cross-sectional view that shows an embodiment of an infrared inspection device of the present invention.

In the appended figures, similar components and/or features may have the same reference label.

### DETAILED DESCRIPTION OF THE PREFERRED EMBODIMENT

The ensuing description provides preferred exemplary embodiments only, and is not intended to limit the scope, applicability or configuration of the invention. Rather, the ensuing description of the preferred exemplary embodiments will provide those skilled in the art with an enabling description for implementing a preferred exemplary embodiment of the invention. It should be understood that various changes may be made in the function and arrangement of elements without departing from the spirit and scope of the invention as set forth in the appended claims.

Embodiments of the present invention disclose a unique sequence of process steps that prepare multicrystalline substrates as “handle wafers” for a subsequent bonding process to “device layer” quality materials which overcomes the limitations of the prior art. Some embodiments provide a method for using less-expensive substrate materials such as multicrystalline silicon for the production of silicon wafer substrates with TTV of less than 0.5 nm, which are suitable for use in SOI, MEMS, MOEMS and other applications which require TTV tolerances around this range.

In one embodiment of the invention, the invention provides a method for preparing multicrystalline substrates as “handle wafers” for subsequent bonding to “device layer” quality materials. In one step, starting with a suitable substrate such as multicrystalline silicon, the substrate surface is prepared for layer transfers by polishing the substrate to reduce surface roughness to about 5 nm. In another step, a filler layer of polycrystalline silicon is transferred to the face of the polished substrate to a predetermined thickness, thus filling in surface defects remaining after the initial polishing step so that the substrate is substantially free of indications of the multicrystalline arrangement. In another step, a final polishing step is performed to form a substantially smooth upper surface on the substrate. By these steps, multicrystalline substrates can be prepared with surface roughness of twenty Angstroms or less, which is suitable for defect-free bonding to device-layer materials in this embodiment.

In another embodiment, the invention provides an improved method for polishing substrates. In one step, a rough polishing step is performed using a weakly alkaline slurry. In another step, the composition of the polishing slurry is gradually changed by feeding neutral polishing slurry to the polishing pad and gradually reducing the supply of rough polishing slurry. The surface roughness after this embodiment of the invention is typically 0.5 nm or less.

In a further embodiment, the invention provides a method for detection of hidden bonding flaws in multiple-bonded wafers. In one step, infrared light is transmitted through a first side of a multiple bonded wafer sample. In another step, the infrared radiation is received after it passes through a second side of the said multiple bonded wafer sample, opposite to the first side. In a further step, received infrared radiation is converted into an electronic signal in which bonding defects appears as local maxima in said signal.

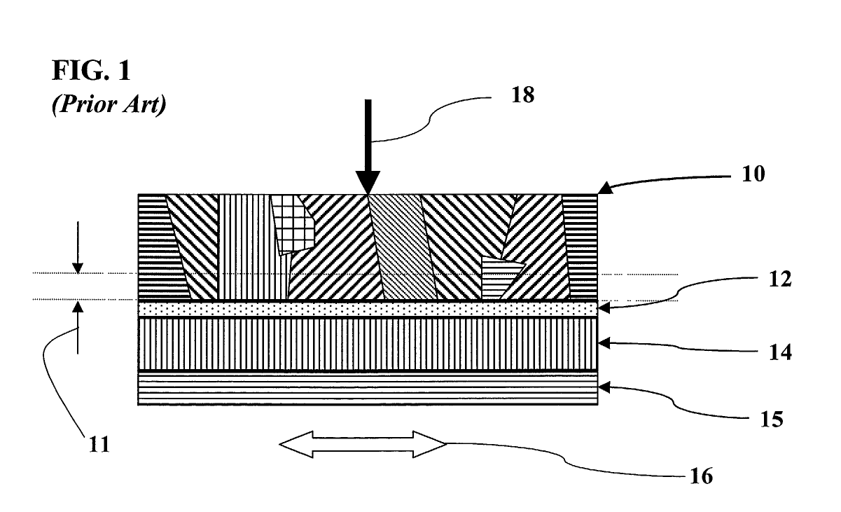

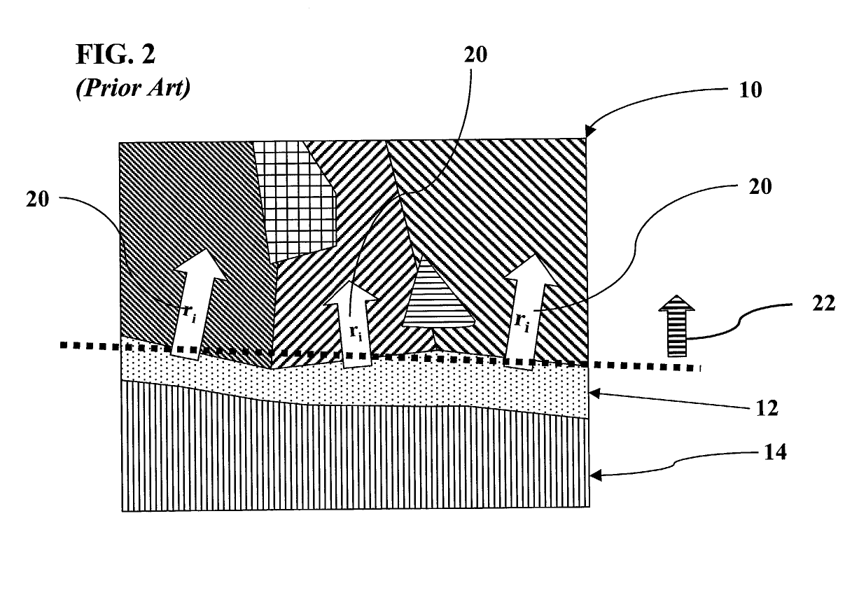

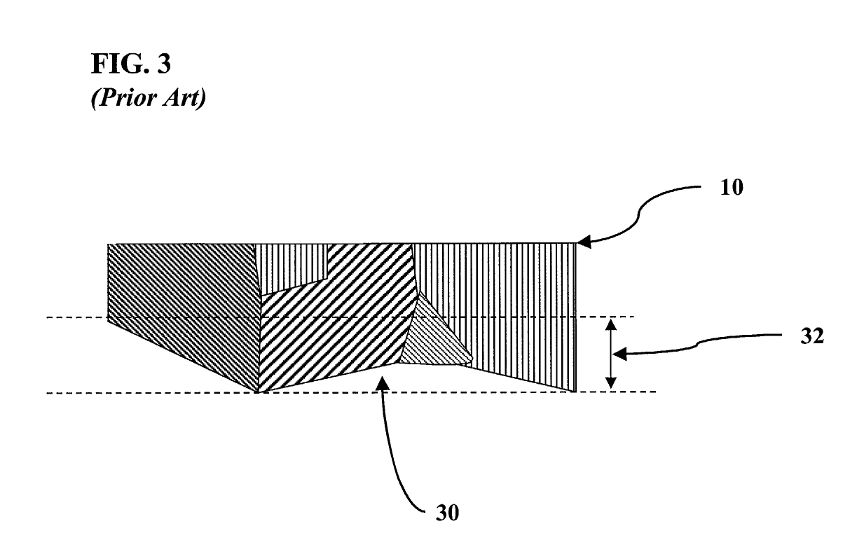

Referring first to FIG. 1 to illustrate a prior art chemical-mechanical planarization (CMP) process in order to better understand the present invention, a ground multicrystalline wafer 10 is polished in a chemical-mechanical planarization (CMP) process, using a polishing pad 14, mounted to a flat and solid polishing platen 15 and a polishing slurry 12. The polishing slurry 12 is typically a high pH (greater than 10.0) slurry of silica (SiO₂) which chemically etches a surface of the wafer 10 while the silica particles mechanically remove the reaction products through friction with a polishing pad 14. Under controlled conditions, macroscopically flat and microscopically smooth surfaces can be obtained on monocrystalline substrate materials. To achieve economically relevant polishing removal rates, a pH level of 10-11.5 is commonly used to remove about 15 μm of material off the surface. For a given pH, the applied downward force 18 and the relative motion 16 of the wafer against the platen serve to control the polish removal rates. At the beginning of the process, the wafer 10 is macroscopically flat from a mechanical grinding or lapping process. The purpose of polishing is to remove a shallow damage zone 11 containing imperfections from the grinding step. FIG. 2 illustrates the situation after several μm of silicon have been polished off. A polish rate 20 (rᵢ) for each individual crystal orientation present at the surface is slightly different. In fact, the more alkaline the slurry 12 is, the greater the differential in relative removal rates between the different grain orientations. Consequently, the formerly flat surface becomes uneven, as the removal front 22 moves further into the bulk silicon. The soft polishing pad 14 accommodates the various surface elevations to a certain degree. As the local contact pressure at a peak gets larger, the removal rate for a slow polishing crystal orientation increases and keeps the maximum peak to valley variation within certain limits, depending on the thickness and hardness of the polishing pad 14. Nevertheless, as illustrated in FIG. 3, the prior art generates dimensional variations 32 in the surface of +/−5 nm or more. A front side 30 of these wafers cannot be used as substrate for wafer bonding since the variation in surface elevation (32) exceeds the required maximum tolerable level for wafer bonding of 0.2-0.5 nm.

One embodiment of the present invention resolves this issue by first applying a controlled, purely mechanical fine-grinding step, followed by a brief “rough polishing” step at a pH level around 9, which is in turn followed by “fine polishing” in a near-neutral (pH approximately 7) final polishing slurry. This polishing is preferably done on a machine that simultaneously polishes a front side and a back side of the wafer. During the rough polishing step, the slurry consists of a dispersion of larger SiO2 particles in a slightly alkaline aqueous solution. This changes the balance of the chemical/mechanical polishing process reactions towards the mechanical side, which is indifferent to the various multi-crystalline orientations present at the surface. When the shallow surface regions that contain the grinding damage 11 are removed by the rough polishing step, the composition of the polishing slurry 12 is changed by first feeding a neutral final polishing slurry simultaneously with the rough polishing slurry to the polishing pad, and then slowly reducing the supply of the rough polishing slurry until only the final polishing slurry is present. Polishing is then continued for a few more minutes to obtain the required smoothness for bonding. During this step or at the end of this step a surfactant may be added to improve the surface quality among other reasons. The wafers may then be finished by polishing on another, yet softer finishing pad. The wafers obtained from this embodiment of the process have the same macroscopic flatness as conventional, monocrystalline wafers while revealing typically less than 0.5 nm roughness, sufficient for most bonding applications.

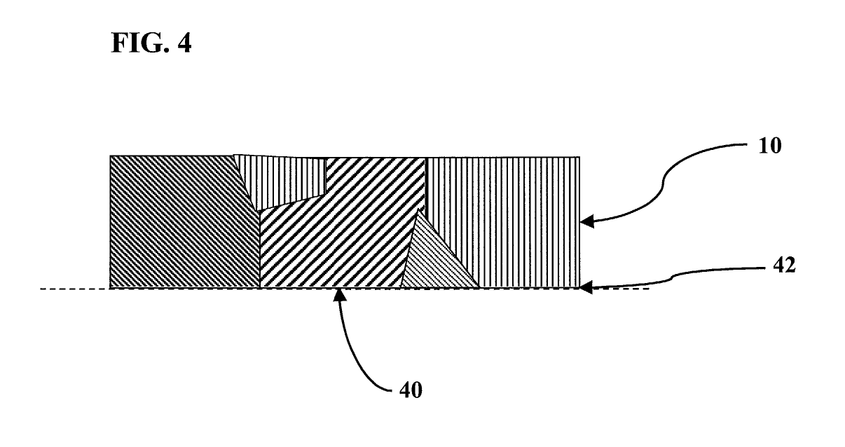

FIG. 4 illustrates the resulting surface after polishing in one embodiment of with the present invention. The resulting variation in the surface elevation 42 in the new front side 40 is too small to be shown to scale in the drawing, being typically much less than 0.5 nm in height.

In one embodiment of the present invention, the pH level of the rough polishing slurry is adjusted by adding concentrated TMAH (Tetramethylammonium Hydroxide) to a chemically neutral slurry mixture containing SiO2 particles and water. This allows adjusting the pH level in a wide range to optimize the balance between mechanical and chemical removals. A side benefit of using TMAH as base chemical is that it also efficiently removes the reaction products from the polishing pad, thus maintaining high removal rates and constant polishing conditions over an extended lifetime of the polishing pads.

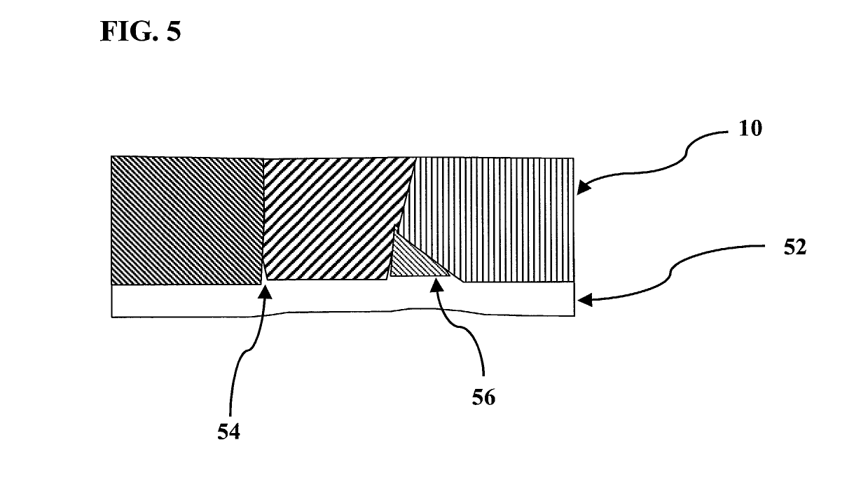

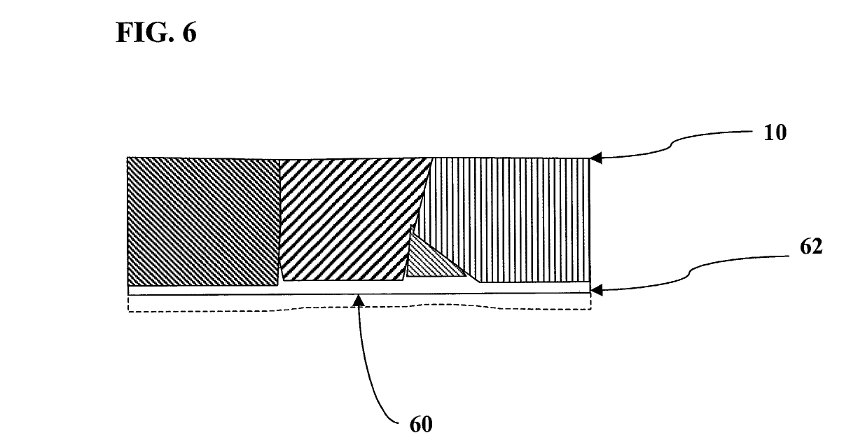

In another embodiment of our invention and referring to FIG. 5, the surface of a multicrystalline handle wafer 10 is covered by a “filler” layer 52 after the aforementioned polishing step to cover and fill all crevices 54 and steps 56 between grain boundaries before polishing. FIG. 6 depicts an embodiment of this wafer 10 after polishing, wherein a substantial part of a filler layer 62 has been removed by polishing, leaving a flat and smooth new surface 60.

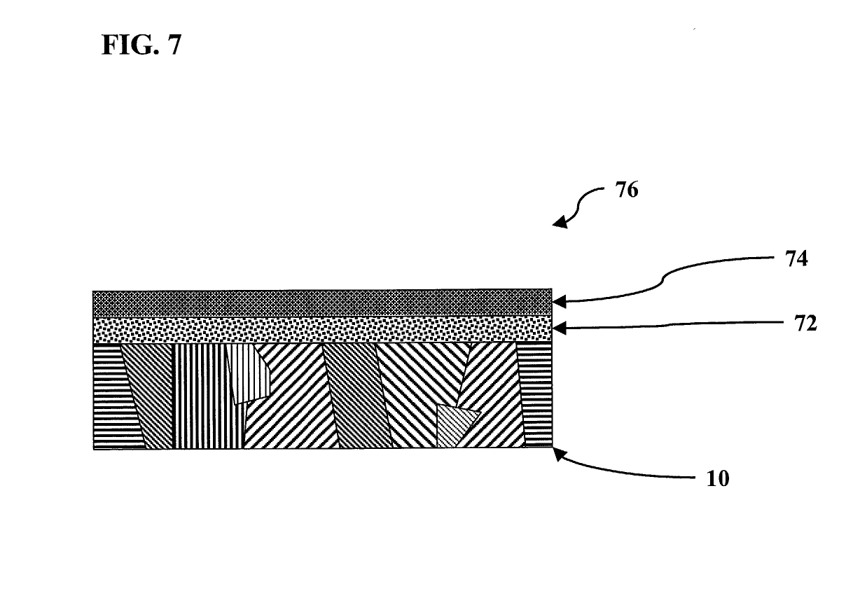

The filler layer 62 can include any or all of the following materials: polycrystalline (fine grain) silicon or SiGe layers, oxide layers, SiC or Si3N4 layers, and other semiconductor processing compatible materials. These layers 62 may be deposited by chemical vapor deposition (CVD) or sputtering processes well known in the art, to a thickness ranging from 100-10,000 nm. These layers 62 not only fill in and cover any crevices and steps between grain boundary layers of the original multicrystalline substrate, but they also provides a more homogeneous material with smaller and more randomly distributed crystal orientations at the surface for the subsequent final polishing so that even smoother surfaces can be obtained in this embodiment. These layers 62 can also act as an insulation layer in an embodiment of a silicon-on-insulator (SOI) structure. Further, these layers 62 can also be made from materials with a higher thermal conductivity than silicon to improve the removal of heat from the active device regions near the front surface. FIG. 7 illustrates n embodiment of a finished wafer assembly 76 consisting of the multicrystalline substrate 10, an isolating layer 72, and a device layer 74 obtained from a donor wafer after further processing.

A further improvement of the present invention is the use of a double-sided polishing step where the polishing is performed as described above, but on both sides simultaneously. When this polishing is done via the simultaneous double-sided polishing technique, no deterioration of macroscopic flatness is observed, unlike in conventional polishing where the typical wafer mounting procedures add to the decrease in flatness.

A further element of the present invention is the recycling (or regeneration) of the donor wafers for the device layers. As described elsewhere, after bonding and splitting-off the device layer from the handle or donor wafer, the remaining donor wafer can be reused for another layer transfer after polishing. If this polishing is done on conventional polishers, the initial damage from the splitting process first increases the roughness during the initial polishing steps, such that the average flaw size is greater after initial polishing. When polishing is continued, i.e. at larger removals, the roughness is reduced as originally intended once the undisturbed lower levels of the donor wafer are reached by the polishing front. Since a double-sided improved CMP polishing process embodiment of the present invention does not increase the roughness in the initial polishing phases, a smaller amount of material needs to be removed to obtain perfectly bondable surface quality. After completion of a double-sided polishing (DSP) step, the donor wafer is returned to the same cleanliness and surface roughness as a “virgin” wafer, thus allowing two or more uses of the same donor wafer with no loss of bonding quality.

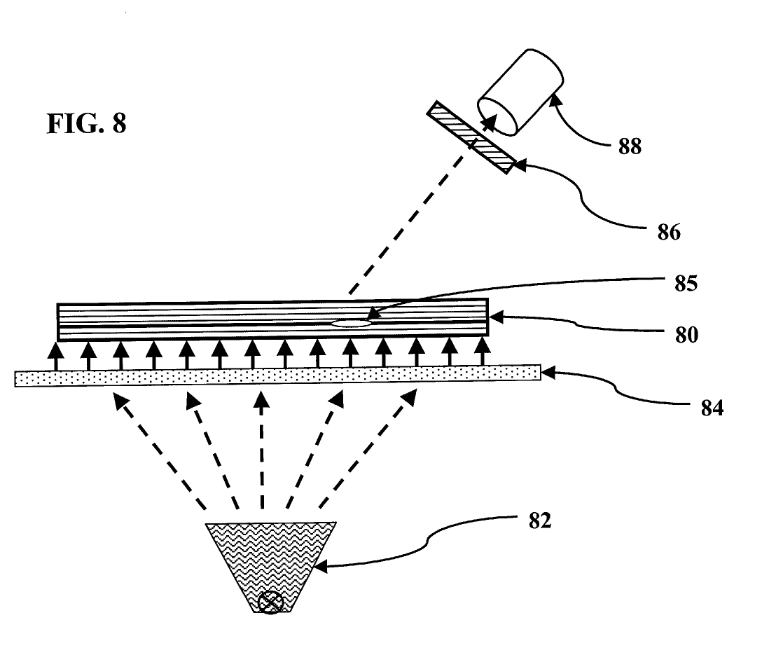

FIG. 8 illustrates an embodiment of the inspection step of the invention, according to which an inspection for the presence of voids in the bonding interface is conducted in situ. The bonded wafer assembly 80 is evenly illuminated with electromagnetic radiation emitted from an infrared light source 82 and passed through a diffuser plate 84 made from a silicon wafer of substantially equal doping as the substrate material 80. An infrared-sensitive charged couple device (CCD) video camera 88 receives radiation passing through an infrared bandpass filter 86 and detects the presence of a bonding defect 85 in the transmitted light. Defects in the bonding interface will appear as peaks in infrared light detected at the camera. Using a variety of methods well-known in the art, including but not limited to visual inspection using a standard computer monitor, those skilled in the art can appreciate that detection of bond imperfections will be easily accomplished.

A number of variations and modifications of the invention can also be used. For example, in one embodiment of the invention a temperature-controlled wafer chuck is installed on a breadboard and used as the infrared light source for the substrate sample that is positioned on the chuck. In another embodiment, the image data collected by the CCD camera 88 can be stored in a computer memory system. A stored program loaded from a computer system hard disk drive could then load said data and use well-known digital signal processing means to automatically detect and precisely locate flaws in the wafer-to-wafer bonds.

In another embodiment of the invention, the filler layer 52 is an approximately 1 micron thick APCVD poly layer on a rough polished wafer 10. With a grain size in the sub-micron range (typical of poly), this layer can be smoothened by the modified CMP process of the present invention by removing 0.5 microns or less of the filler layer. The layer could be deposited by plasma CVD, epitaxy, or any other layer transfer process suitable for the materials to be transferred. Note also that while grinding is the normal method for preparing a rough surface for the method of the present invention, other rough preparation methods such as wet-chemical etching, plasma etching, single-sided lapping or polishing can be used to prepare the surface for the method of the present invention.

In another embodiment, the enhanced CMP process described above, in which the slurry pH is gradually brought to neutrality, can be performed in single-side polishing processes as well as the double-sided process as emphasized herein, without any modifications.

While the principles of the invention have been described above in connection with specific apparatuses and methods, it is to be clearly understood that this description is made only by way of example and not as limitation on the scope of the invention.

What is claimed is:

1. A method for preparing multicrystalline substrates as handling wafers for subsequent bonding to device layer materials, the method comprising the steps of:
providing an initial multicrystalline substrate;
polishing the multicrystalline substrate to reduce surface roughness to about 5 nm;
forming a filler layer overlying the face of the substrate to a predetermined thickness, the filler layer comprising a surface that is substantially free from indications of the multicrystalline arrangement; and
further polishing the surface of the filler layer to form a substantially smooth upper surface on the substrate,
wherein the substantially smooth upper surface is characterized by a surface roughness of twenty Angstroms or less.

2. The method of claim 1, wherein the initial substrate is selected from a polycrystalline silicon wafer, a glass substrate, a ceramic substrate, an organic film, a metal substrate, and an amorphous wafer.

3. The method of claim 1, wherein the initial substrate has a typical crystalline dimension of about 0.5 to 10 millimeters in size.

4. The method of claim 1, wherein the filler layer is selected from a CVD oxide, and a polycrystalline silicon.

5. The method of claim 1, wherein the filler layer is removed to a thickness of one half or more of the predetermined thickness.

6. The method of claim 1, wherein the filler layer is a polycrystalline silicon, the polycrystalline being formed using a low pressure chemical deposition technique.

7. The method of claim 1, wherein the filler layer is chosen from the group consisting of an insulating layer andor a composite layer.

8. The method of claim 1, wherein the surface roughness is five Angstroms or less.

9. The method of claim 1, wherein the filler layer is made by a chemical deposition process or a sputtering process.

10. The method of claim 1, wherein the substrate is a ground substrate or unpolished substrate.

11. The method of claim 1, wherein the polishing process is a chemical mechanical polishing technique comprising:
applying a mechanical fine-grinding step;
applying a rough polishing step using a weakly alkaline slurry;
changing the composition of the slurry by feeding a neutral polishing slurry to the polishing pad and gradually reducing supply of rough polishing slurry; and
wherein surface roughness after polishing is 0.5 nm or less.

12. The method of claim 1, wherein the polishing process is a chemical mechanical polishing comprising:
applying a mechanical fine-grinding step;
applying a rough polishing step using a weakly alkaline slurry;
adding TMAH to the slurry to adjust the alkalinity of the slurry for increased removal rates while maintaining material removal rates relatively constant between various grain regions of the substrate; and
effecting a controlled transition to a second slurry composition to obtain microscopically smooth surfaces;
wherein surface roughness after polishing is 0.5 nm or less.

13. The method of claim 1, wherein the polishing process is a double-sided chemical mechanical polishing technique comprising:
applying a mechanical fine-grinding step;
applying a rough polishing step using a weakly alkaline slurry;
changing the composition of the slurry by feeding a neutral polishing slurry to the polishing pad and gradually reducing supply of rough polishing slurry; and
wherein surface roughness after polishing is twenty Angstroms or less.

14. The method of claim 1, wherein the polishing process is a double-sided chemical mechanical polishing technique in which polishing is done on a double-sided polishing machine to polish front and back sides of the substrate simultaneously, comprising:
applying a mechanical fine-grinding step;
applying a rough polishing step using a weakly alkaline slurry;
adding TMAH to the slurry to adjust the alkalinity of the slurry for increased removal rates while maintaining material removal rates relatively constant between various grain regions of the substrate;
effecting a controlled transition to a second slurry composition to obtain microscopically smooth surfaces;
wherein the front and back side each achieve a flatness of 0.5 micron or less; and
the front side achieves a roughness of 0.5 nm or less.

15. Electronic devices made from bonded assemblies prepared using the method of claim 1.

16. Micro-Electro-Mechanical Structures (MEMS) made from bonded assemblies prepared using the method of claim 1.

17. Micro-Opto-Electro-Mechanical Structures (MOEMS) made from bonded assemblies prepared using the method of claim 1.

18. A method for polishing substrates, the method comprising steps of:
applying a rough polishing step using a weakly alkaline slurry;
changing the composition of the slurry by feeding a neutral polishing slurry to the polishing pad and gradually reducing supply of rough polishing slurry; and
wherein surface roughness after polishing is 0.5 nm or less.

19. The method of claim 18, wherein the polishing is performed on a double-sided polishing machine to polish front and back sides of said substrate simultaneously.

20. Electronic devices made from bonded assemblies prepared using the method of claim 18.

21. Micro-Electro-Mechanical Structures (MEMS) made from bonded assemblies prepared using the method of claim 18.

22. Micro-Opto-Electro-Mechanical Structures (MOEMS) made from bonded assemblies prepared using the method of claim 18.

23. A method for detection of hidden bonding flaws in multiple bonded wafers, the method comprising steps of:
transmitting infrared radiation through a first side of a multiple bonded wafer sample;
receiving the scattered infrared radiation exiting from a second side of said sample, said second said being opposite from said first side; and
converting said received radiation into an electronic signal in which defects appear as local maxima of said signal.
